(19) United States
(12) Patent Application Publication
(10) Pub. No.: US 2002/0141147 A1
(43) Pub. Date: Oct. 3, 2002

(54) Electronic apparatus having a slidable expansion card slot

(76) Inventor: Tetsuo Ando, Chigasaki-shi (JP)

Correspondence Address: Pillsbury Winthrop LLP, Suite 2800, 725 South Figueroa Street, Los Angeles, CA, 90017-5406, US

(21) Appl. No.: 10/107,645

(22) Filed: Mar. 27, 2002

(30) Foreign Application Priority Data
Mar. 28, 2001 (JP) 2001-093873

(51) Int. Cl. H05K 5/00

(52) U.S. Cl. 361/684; 361/681

(57) ABSTRACT

A slide chamber is disposed in a lid body of a notebook PC, and a card slot for inserting/attaching a Bluetooth card or an SD memory card is slidably disposed in the slide chamber. The card slot is disposed so as to be slidable between an upper position in which the card partly projects outside the lid body and a lower position in which the card is contained in the lid body.

### CROSS-REFERENCE TO RELATED APPLICATIONS

This application is based upon and claims the benefit of priority from prior Japanese Patent Application No. 2001-093873, filed Mar. 28, 2001.

### BACKGROUND OF THE INVENTION

1. Field of the Invention

The present invention relates to electronic apparatuses to which expansion cards (media cards) such as a secure digital (SD) card can be attached.

2. Description of the Related Art

As an electronic apparatus, for example, a notebook-size personal computer (hereinafter referred to as a notebook PC) including a card slot to which expansion cards such as an SD card are attached are known. In general, an SD memory card is known as the SD card.

When a controller module is built in the SD memory card, the card can have various functions of an input/output (I/O) card. For example, the I/O cards having functions of Bluetooth, LAN, GPS, and the like are considered.

Bluetooth is a short-distance radio communication standard, and uses an industrial science medical (ISM) band of 2.4 GHz to realize radio communication usually within 10 m, or within 100 m.

The SD card basically has a dimension of 32 mm in length and 24 mm in width. However, since the Bluetooth card has an antenna portion, the longitudinal dimension is set to be longer than a reference dimension of 32 mm. Therefore, when the Bluetooth card is attached to the card slot of the notebook PC and used, a tip end of the Bluetooth card, that is, an antenna portion, projects from a housing of the notebook PC.

Therefore, when the notebook PC with the Bluetooth card attached thereto as described above is carried, the tip end of the Bluetooth card projecting from the housing may be easily broken. When the Bluetooth card is detached from the card slot during the carrying of the notebook PC, there is no danger of damaging the card.

However, in this case, every time the notebook PC is moved, an operation of detaching the Bluetooth card from the card slot is necessary and troublesome. Moreover, in this case, it is necessary to keep the Bluetooth card removed from the card slot, and there is a possibility that the Bluetooth card is lost.

U.S. Pat. No. 6,104,607 to Behl discloses an expansion card having a fan to cool a notebook PC via the card slot, such as a PCMCIA card slot. However, like the prior art expansion card slot above, the cooling fan portion of the cooling fan card also projects outward from the main body of the notebook PC, making it prone to being broken off or damaged during transportation of the notebook PC. Accordingly, every time the notebook PC is to be moved, an operation of detaching the cooling fan card from the card slot is also required and inconvenient.

### BRIEF SUMMARY OF THE INVENTION

An object of the present invention is to provide an electronic apparatus in which an expansion card can easily and securely be handled.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an appearance of a notebook PC according to an embodiment of the present invention;

FIG. 2 is a main-part sectional view showing a state in which a Bluetooth card is attached to a card slot of the notebook PC of FIG. 1;

FIG. 3 is a main-part sectional view showing a state in which the Bluetooth card is contained in a housing;

FIG. 4 shows a side view and rear view of the Bluetooth card;

FIG. 5 is a partially sectional view showing a connection structure of the Bluetooth card;

FIG. 6 is a partially sectional view showing the vicinity of an opening of a slide chamber in an enlarged manner; and

FIGS. 7 and 8 are main-part sectional views showing a state in which an SD memory card is attached to the card slot.

### DETAILED DESCRIPTION

Embodiments of the present invention will be described hereinafter with reference to the accompanying drawings.

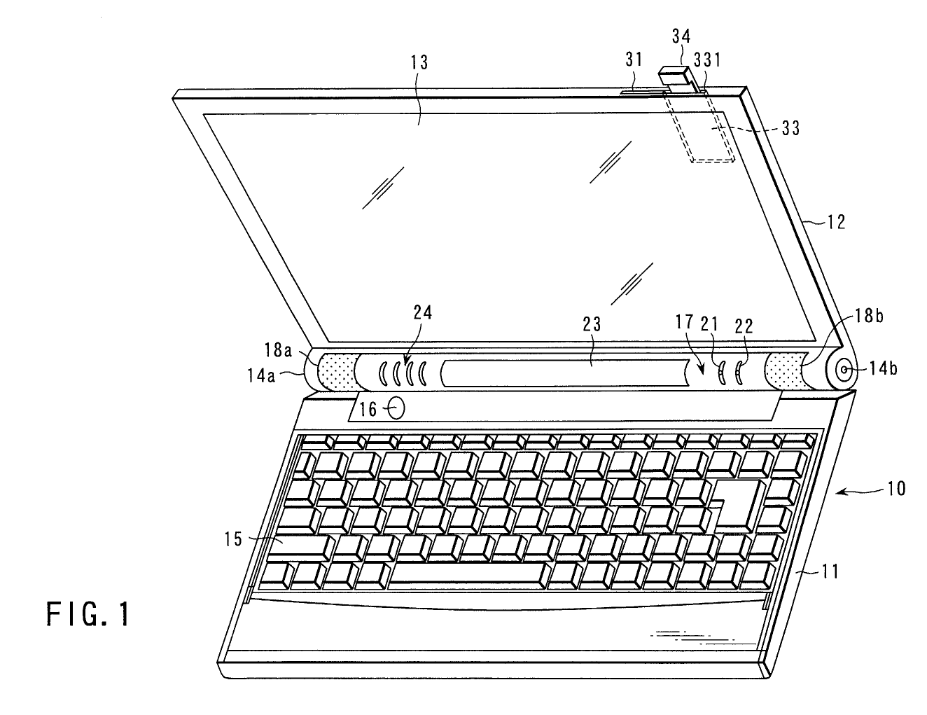

FIG. 1 shows an appearance perspective view of a notebook PC 10 as an electronic apparatus according to an embodiment of the present invention.

The notebook PC 10 has a main body 11 and a lid body 12. A liquid crystal display (LCD) 13 is disposed on an inner surface of the lid body 12. The lid body 12 is rotatably attached to a back of the main body 11 via hinges 14a, 14b.

A keyboard 15 and power switch 16 are disposed on an upper surface of the main body 11 opened/closed by the lid body 12. A circuit substrate, and the like are disposed in the main body 11. A console panel 17 is disposed on a rear end of the main body 11, and speakers 18a, 18b are disposed on opposite sides of the panel.

The console panel 17 includes a selection button 21 for selecting various applications such as Internet, electronic mail, and music reproduction, a volume button 22, a sub LCD 23, and four function designation buttons 24.

Moreover, a slide chamber 33 is disposed in the lid body 12. The slide chamber 33 is disposed on a back surface side of a liquid crystal display 13. A card slot 30 described later is slidably disposed in the slide chamber 33. The slide chamber 33 has an open end in an upper end of the lid body 12 so that expansion cards such as an SD card can be inserted into the chamber via the upper end of the lid body 12. An openable/closable cover 31 is provided in an opening 331 of the slide chamber 33, to prevent foreign particles from interring the chamber 33.

The cover 31 is disposed so as to be slidable between a shown position in which the opening 331 of the slide chamber 33 is opened and a position (not shown) in which the opening 331 is closed. FIG. 1 shows that the cover 31 is opened and a Bluetooth card 34 described later is attached to the card slot 30 in the slide chamber 33. Additionally, the Bluetooth card 34 is not attached, and the cover 31 is then slid to the position in which the opening 331 of the slide chamber 33 is closed.

Although the slide chamber 33 is illustrated in FIG. 1 to be at one side of the lid body 12, in a preferred embodiment, the slide chamber 33 is disposed at the center of the top of the lid body 12. This arrangement provides for better transmission/reception of a radio communication expansion card 34, such as a Bluetooth card.

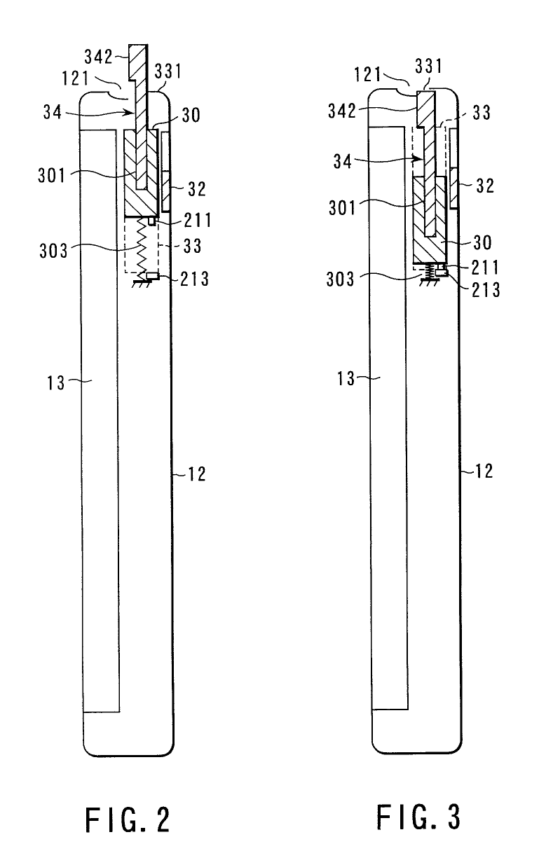

As shown in FIGS. 2 and 3, the card slot 30 is formed in a substantially rectangular block shape, and has a slot 301 for attaching the Bluetooth card 34. This card slot 30 can be disposed in an upper position (first position) shown in FIG. 2 and a lower position (second position) shown in FIG. 3 in the slide chamber 33.

A length of the slide chamber 33, a depth of the slot 301, and the like are set so that the tip end of the Bluetooth card 34 attached to the slot 301 projects outwards from the opening 331 of the slide chamber 33 with the card slot 30 disposed in the upper position, and the tip end of the Bluetooth card 34 attached to the slot 301 does not project from the opening 331 of the slide chamber 33 with the card slot 30 disposed in the lower position.

The card slot 30 is constantly pushed upwards by a spring 303 extended in the slide chamber 33. Moreover, the card slot 30 is held in the upper and lower positions by a known switch mechanism. The switch mechanism may be of a so-called push-push type. The switch mechanism is switched, when the tip end of the Bluetooth card 34 attached to the card slot 30 is pushed downwards against a pushing force of the spring 303 and the card slot 30 is pushed downwards to a position slightly lower than the lower position. The card slot 30 is thereby held alternately in the upper and lower positions.

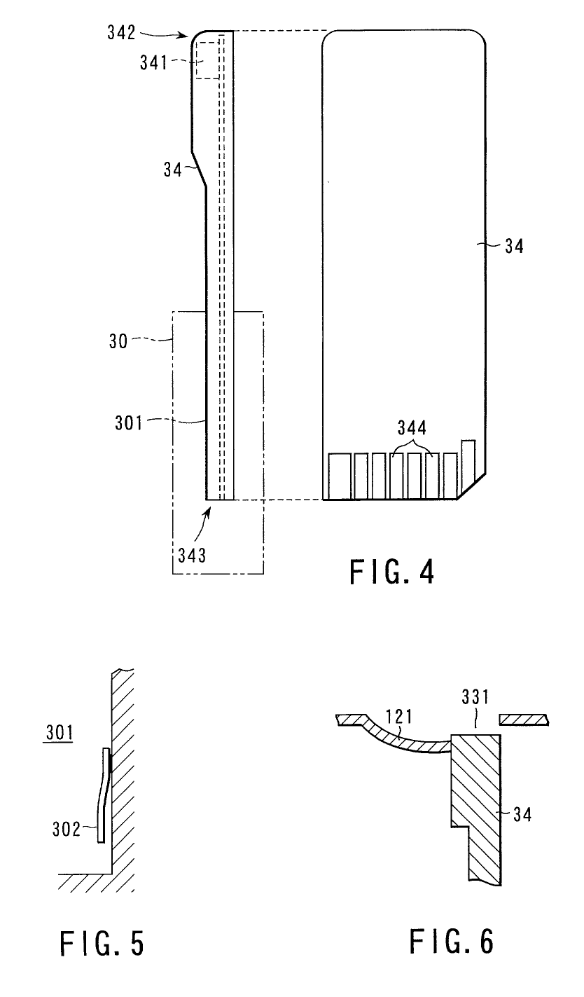

As shown in FIG. 4, the Bluetooth card 34 has a relatively thick function expansion portion 342 including an antenna 341 in a tip end. That is, the Bluetooth card 34 has a longitudinal dimension larger than that of a basic SD card which does not have any function expansion portion. Moreover, the Bluetooth card 34 has a plurality of connection terminals 344 on a rear surface thereof in a base end 343 thereof inserted in the slot 301 of the card slot 30.

As shown in FIG. 5, on the inner wall of the slot 301, a plurality of connectors 302 are disposed, and electrically connected to the plurality of connection terminals 344 of the Bluetooth card 34, while the Bluetooth card 34 is attached to the slot 301. Each connector 302 has a leaf spring structure whose base end is fixed to the inner wall of the slot 301, and is brought into press contact with each connection terminal 344 of the Bluetooth card 34.

Here, an operation for attaching and detaching the Bluetooth card 34 will be described.

The card slot 30 is disposed in the upper position shown in FIG. 2 in an initial state. When the Bluetooth card 34 is attached, the cover 31 is opened, and the Bluetooth card 34 is inserted into the slide chamber 33 via the opening 331, and attached to the slot 301 of the card slot 30. Thereby, the connection terminal 344 of the Bluetooth card 34 is electrically connected to the connector 302 of the slot 301, and the tip end of the Bluetooth card 34 projects outwards from the opening 331. That is, the function expansion portion 342 of the Bluetooth card 34 projects outwards from the lid body 12, and the Bluetooth card 34 is held in an operatable state.

For example, when the notebook PC 10 is carried, in the present embodiment, the Bluetooth card 34 projecting from the lid body 12 as described above is contained in the lid body 12 without being extracted.

That is, a user pushes the tip end of the Bluetooth card 34 projecting from the housing of the lid body 12 with fingers as shown in FIG. 2, and pushes the card slot 30 together with the Bluetooth card 34 downwards from the upper position. In this case, as shown in FIG. 6, the user's finger enters a dent 121 formed in the upper end of the lid body 12, and the card slot 30 is pushed slightly downwards from the lower position. Thereby, the aforementioned switch mechanism operates. Thereafter, when the user releases the tip end of the Bluetooth card 34, the card slot 30 is pushed slightly upwards by the spring 303, and the card slot 30 is held in the lower position.

In this state, the tip end of the Bluetooth card 34 is contained in the housing of the lid body 12, the cover 31 is slid to close the opening 331, and the Bluetooth card 34 is brought in an inoperative state. Additionally, to contain the Bluetooth card 34 in the housing, a width of the opening 331 of the slide chamber 33 is formed to be larger than at least a thickness of the function expansion portion 342, so that the thick function expansion portion 342 of the Bluetooth card 34 can pass through the opening.

When the Bluetooth card 34 contained in the lid body 12 as described above is again held in an operation state, first the cover 31 is opened, and the tip end of the Bluetooth card 34 is again pushed inwards. Thereby, the switch mechanism again operates, and the card slot 30 is pushed upwards by the spring 303, and disposed in the upper position shown in FIG. 2.

Moreover, according to one embodiment of the present invention, a projection 211 may be mounted on the bottom of the card slot 30, and a corresponding switch 213 may be mounted at the bottom of the slide chamber 33. The switch 213 is in a power supply line that provides the expansion card 34 with electric power. Accordingly, when the card slot 30 is retracted into the lid body 12 (as in FIG. 3), the projection 211 pushes down on the switch 213 and power is cut off from the expansion card 34. And when the card slot 30 is in the upper position (as in FIG. 2), the switch 213 is not depressed and power is provided to the expansion card 34. The projection 211 and switch 213 provide one mechanism to control power to the expansion card 34.

Thereafter, the Bluetooth card 34 is extracted from the card slot 30 by the user as the occasion demands.

As described above, according to the present embodiment, the Bluetooth card 34 can be contained in the housing of the notebook PC 10. Therefore, during the carrying and moving of the notebook PC 10, there is no possibility that the function expansion portion 342 of the Bluetooth card 34 projects from the housing and contacts people, objects, and the like, and the Bluetooth card 34 can securely be prevented from being damaged. Moreover, different from the conventional art, according to the present embodiment, it is unnecessary to extract the Bluetooth card 34 every time the notebook PC is carried, and an operation burden can be reduced. Additionally, it is unnecessary to keep the extracted Bluetooth card 34, and there is no fear that the Bluetooth card 34 is lost.

In the aforementioned embodiment, the attaching/detaching of the Bluetooth card 34 having a relatively large longitudinal dimension with respect to the card slot 30 has been described. However, a basic SD card having a longitudinal dimension smaller than that of the Bluetooth card 34, and the like are also attached to the card slot 30.

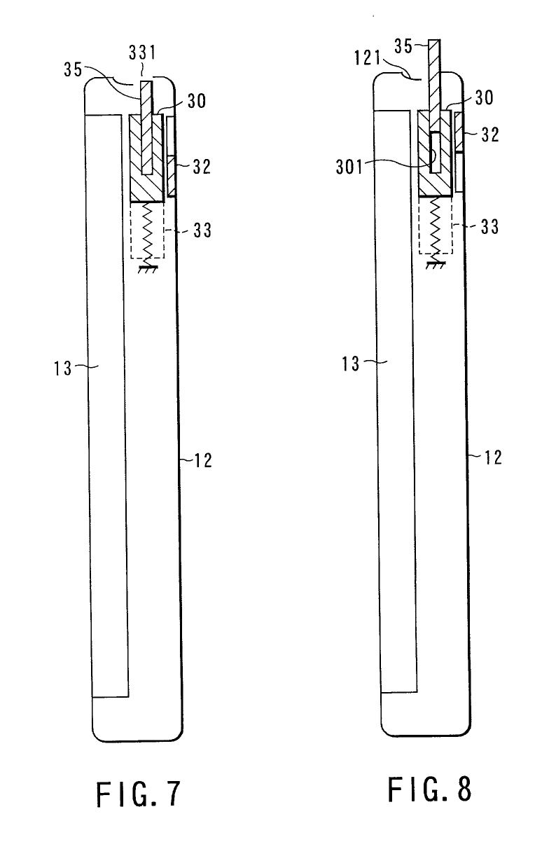

FIGS. 7 and 8 show an example in which an SD memory card 35 having a reference dimension is attached as the SD card to the card slot 30. With the SD memory card 35 attached to the card slot 30, even when the card slot 30 is disposed in the upper position as shown in FIG. 7, the SD memory card 35 is contained in the lid body 12. Therefore, when the SD memory card 35 is used, the cover 31 is closed. Additionally, when the SD memory card 35 is used, the card slot 30 may be disposed in either the upper position or the lower position.

When the SD memory card 35 is extracted from the card slot 30, the cover 31 is opened, and an eject button 32 is operated. The eject button 32 is disposed on an outer surface of the lid body 12 of the notebook PC 10, and functions so that the SD memory card 35 is slid upwards from the slot 301 of the card slot 30 disposed in the upper position. When the eject button 32 is operated, the upper end of the SD memory card 35 projects outwards from the lid body 12, and the user can manually take out the SD memory card 35.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

For example, in the above embodiment, the card slot 30 is slid in the slide chamber 33 so that the Bluetooth card 34 is projected and contained. However, the Bluetooth card 34 may be projected or contained by sliding a substrate (not shown) with the card slot 30 disposed thereon.

Moreover, in the above embodiment, a push-push type switch mechanism for switching a slide position of the card slot 30 in two stages is used. However, a switch mechanism for positioning the card slot 30 in the slide chamber 33 in three stages may be used, and the card slot 30 may be held in an eject position in addition to the upper and lower positions. In this case, the eject button 32 for moving the SD card to an extraction position is unnecessary.

Furthermore, a position changeover lever may be disposed instead of the push-push type switch, and the slide position of the card slot 30 may be switched by this lever. In this case, the slide position of the card slot 30 may be switched in either two or three stages.

Additionally, in the above embodiment, the sliding of the card slot 30 to the upper and lower positions has been described. However, the card slot 30 may be fixed, for example, to the upper position. In this constitution, the Bluetooth card 34 or the SD memory card 35 may be slid along the slot 301 of the fixed card slot 30 between the upper position and the lower position. Also, the card 34, 35 may be permanently fixed to the card slot 30, or may be of the removable/detachable type.

According to an embodiment of the present invention, the Bluetooth card 34 has a width of 24 mm, a length of 50 mm, a main body thickness of 2.1 mm, and an end portion being 12 mm long and having a thickness of 5 mm.

Moreover, in the above embodiment, the use of the Bluetooth card 34 or the SD memory card 35 as the SD card has been described. Additionally, I/O cards having various functions of a camera, LAN, GPS, voice recorder, audio player, FM/TV tuner, and the like can also be used. Furthermore, expansion cards other than the SD card may also be used.

Furthermore, in the above embodiment, the card slot 30 disposed in the upper portion of the lid body 12 of the notebook PC 10 has been described, but the card slot 30 may be disposed in a side portion of the lid body 12, or in the main body 11.

Additionally, in the above embodiment, the attaching of the Bluetooth card 34 or the SD memory card 35 to the card slot 30 of the notebook PC 10 has been described, but the structure of the present embodiment may be used in various electronic apparatuses having card slots, such as a mobile phone, mobile information terminal, game apparatus, car navigation, and the like.

What is claimed is:

1. An electronic apparatus, comprising:
a card slot disposed in an apparatus housing and to which an expansion card is to be attached; and
a slide mechanism to slide and hold the expansion card, including a function expansion portion, into a first position in which said function expansion portion projects outwards from said housing and a second position in which said function expansion portion is contained in the housing.

2. The electronic apparatus according to claim 1, wherein said card slot includes a cover in a card insertion portion.

3. The electronic apparatus according to claim 1, wherein said slide mechanism slides the card slot and switches and holds the expansion card into the first position and the second position.

4. The electronic apparatus according to claim 1, wherein said slide mechanism slides a substrate with the card slot disposed thereon and switches and holds the expansion card into the first position and the second position.

5. The electronic apparatus according to claim 1, wherein said slide mechanism slides the expansion card in the card slot and switches and holds the expansion card into the first position and the second position.

6. The electronic apparatus according to claim 1, wherein said card slot holds the expansion card slid into the first position in an operation state, and holds the expansion card slid into the second position in a non-operation state.

7. The electronic apparatus according to claim 1, wherein said expansion card is a secure digital (SD) card.

8. The electronic apparatus according to claim 1, wherein the expansion card is a Bluetooth card.

9. An electronic apparatus, comprising:
a card slot disposed in an apparatus housing and to which an expansion card is to be attached; and
a slide mechanism to slide and hold the expansion card, including a function expansion portion, into a first position in which said function expansion portion projects outwards from said housing, a second position in which said function expansion portion is contained in the housing, and a third position in which the expansion card is taken outwards.

10. The electronic apparatus according to claim 9, wherein said card slot holds the expansion card slid into the first position in an operation state, and holds the expansion card slid into the second position in a non-operation state.

11. The electronic apparatus according to claim 9, wherein said expansion card is a secure digital (SD) card.

12. The electronic apparatus according to claim 9, wherein the expansion card is a Bluetooth card.

13. An electronic apparatus, comprising:
a card slot disposed in an apparatus housing and to which an expansion card is to be attached;
a slide mechanism to slide and hold the expansion card, including a function expansion portion, into a first position in which said function expansion portion projects outwards from said housing and a second position in which said function expansion portion is contained in the housing; and
an eject button to take outwards the expansion card attached to said card slot.

14. The electronic apparatus according to claim 13, wherein said card slot includes a cover in a card insertion portion.

15. The electronic apparatus according to claim 13, wherein said slide mechanism slides the card slot and switches and holds the expansion card into the first position and the second position.

16. The electronic apparatus according to claim 13, wherein said slide mechanism slides a substrate with the card slot disposed thereon and switches and holds the expansion card into the first position and the second position.

17. The electronic apparatus according to claim 13, wherein said slide mechanism slides the expansion card in the card slot and switches and holds the expansion card into the first position and the second position.

18. The electronic apparatus according to claim 13, wherein said card slot holds the expansion card slid into the first position in an operation state, and holds the expansion card slid into the second position in a non-operation state.

19. The electronic apparatus according to claim 13, wherein said expansion card is a secure digital (SD) card.

20. The electronic apparatus according to claim 13, wherein the expansion card is a Bluetooth card.

21. An electronic apparatus, comprising:
a card slot disposed in an apparatus housing;
an expansion card fitted into the card slot, the expansion card having a function expansion portion; and
a slide mechanism to slide and hold the expansion card into a first position in which said function expansion portion projects outwards from said housing and a second position in which said function expansion portion is contained in the housing.

22. The electronic apparatus according to claim 21, wherein the expansion card is fixed to the card slot.

23. The electronic apparatus according to claim 21, wherein the expansion card is removable from the card slot.

24. An electronic apparatus, comprising:
a display panel housing;
a card slot disposed in a top edge of the display panel housing;
an expansion card fitted into the card slot, the expansion card having a function expansion portion; and
a slide mechanism to slide and hold the expansion card into a first position in which said function expansion portion projects outwards from said housing and a second position in which said function expansion portion is contained in the housing.

25. The electronic apparatus according to claim 24, wherein the card slot is disposed at a center of the top edge of the display panel housing.

26. The electronic apparatus according to claim 24, wherein the expansion card is fixed to the card slot.

27. The electronic apparatus according to claim 24, wherein the expansion card is removable from the card slot.

28. The electronic apparatus according to claim 24, wherein the display panel housing is adapted to house a liquid crystal display (LCD).

29. An electronic apparatus, comprising:
a card slot disposed in an apparatus housing;
a secure digital (SD) Bluetooth card fitted into the card slot, the SD Bluetooth card having a width of 24 mm, a length of 50 mm, a main body thickness of 2.1 mm, and a function expansion portion being 12 mm long and having a thickness of 5 mm at an end of the SD Bluetooth card; and
a slide mechanism to slide and hold the SD Bluetooth card into a first position in which said function expansion portion projects outwards from said housing and a second position in which said function expansion portion is contained in the housing.

30. The electronic apparatus according to claim 29, wherein the SD Bluetooth card is fixed to the card slot.

31. The electronic apparatus according to claim 29, wherein the SD Bluetooth card is removable from the card slot.

32. An electronic apparatus, comprising:
an apparatus housing having an outer wall;
a card slot disposed in a card insertion portion of the outer wall, the card insertion portion having a dent;
an expansion card fitted into the card slot, the expansion card having a function expansion portion; and
a slide mechanism to slide and hold the expansion card into a first position in which said function expansion portion projects outwards from said housing and a second position in which said function expansion portion is contained in the housing.

33. The electronic apparatus according to claim 32, wherein the expansion card is fixed to the card slot.

34. The electronic apparatus according to claim 32, wherein the expansion card is removable from the card slot.
